(19) United States
(12) Patent Application Publication
(10) Pub. No.: US 2026/0182353 A1
(43) Pub. Date: Jun. 25, 2026

(54) INTERCONNECT STRUCTURES WITH METAL SILICATE DIELECTRICS

(71) Applicant: International Business Machines Corporation, Armonk, NY (US)

(72) Inventors: SON NGUYEN, Schenectady, NY (US); Vijay Narayanan, New York, NY (US); Takeshi Nogami, Schenectady, NY (US)

(21) Appl. No.: 19/000,853

(22) Filed: Dec. 24, 2024

(51) Int. Cl. H01L 23/532; H01L 23/522; H01L 23/528

(52) U.S. Cl. CPC H10W 20/4403; H10W 20/42; H10W 20/435

(57) ABSTRACT

A semiconductor structure including a back-end-of-line (BEOL) interconnect structure having a plurality of wiring levels. A wiring level of the plurality of wiring levels including a conductive line and two or more vias electrically connecting two or more levels of the plurality of wiring levels. The semiconductor structure having a low-k MₓSi_{y}O_{z} dielectric associated with the conductive line and the two or more vias; the “M” is a metal such as manganese or other disclosed materials.

### BACKGROUND

The present disclosure generally relates to the fabrication of integrated circuits, semiconductors, and the like and, more particularly, to various methods of forming interconnect structures.

The fabrication of interconnect structures can include formation of metallic wiring that connects individual devices within a semiconductor device to one another. Typically, the wiring interconnect network can include line features, which can traverse a specific distance across the chip, and via features, which can connect lines in different levels of the semiconductor device. These two types of features can serve as electrical conductors. Typically, the conducting metal lines and vias are insulated by an interlayer dielectric (ILD), such as electrical insulators including silicon dioxide (SiO₂), fluorine, or carbon-doped silica film (SiCOH) deposited by a plasma enhanced chemical vapor deposition (PECVD), to name a few.

With continuing advancements in technology comes constant demands for both improved functionality and reduction in the size of semiconductor devices. As a consequence, there is a demand for reductions in a footprint of the interconnect structure that forms the metallic circuitry within the semiconductor device without jeopardizing functionality and longevity. One option to reduce the footprint of the interconnect structure is to minimize the separation between adjacent features in the semiconductor device. However, unwanted capacitive coupling can occur between adjacent features, such as adjacent metal lines in back-end-of-line (BEOL) interconnect structures, adjacent contacts (e.g., middle-of-the-line (MOL) device contacts) of front-end-of-line (FEOL) devices, etc. Such parasitic capacitances can lead to degraded performance of the semiconductor device. For example, capacitive coupling between transistor contacts can lead to an increased gate-to-source or gate-to-drain parasitic capacitances adversely impacting the operational speed of a transistor, increasing energy consumption, etc. Additionally, unwanted capacitive coupling between adjacent metal lines of a BEOL interconnect structure can lead to increased resistance-capacitance delay (or latency), crosstalk, increased dynamic power dissipation within an interconnect stack, etc.

In an effort to reduce parasitic coupling between adjacent conductive features, the semiconductor industry has adopted the use of low dielectric constant (low-k) dielectrics as insulating materials for MOL and BEOL interconnect levels of semiconductor devices. The advent of low-k dielectrics coupled with aggressive scaling, however, has led to significant challenges in the long-term reliability of such low-k materials. For example, low-k time-dependent dielectric breakdown (TDDB) is commonly considered a critical issue because low-k materials generally have weaker intrinsic breakdown strength than traditional SiO₂ dielectrics. In general, TDDB refers to the loss of the insulating properties of a dielectric when it is subjected to voltage/current bias and temperature stress over time. TDDB results in unintended conductance between two adjacent features causing an increase in leakage current and, thus, degrading performance in nano-scale integrated circuits. The phenomenon is highly dependent upon the electrical field between the metal features as regions with higher electrical fields are more susceptible to TDDB failure. Consequently, the distance between metal features is critical to maintain as metal features that are too close can often have very high electrical fields between them and will likely fail by TDDB.

### BRIEF SUMMARY

Principles of the invention provide techniques for interconnect structures with metal silicate dielectrics. In one aspect, an exemplary semiconductor structure includes a semiconductor structure including a back-end-of-line (BEOL) interconnect structure having a plurality of wiring levels, in which a wiring level of the plurality of wiring levels includes a conductive line and two or more vias electrically connecting two or more levels of the plurality of wiring levels. The semiconductor structure further includes a low-k MₓSi_{y}O_{z} dielectric associated with the conductive line and the two or more vias (the “M” is a metal such as manganese or other materials disclosed herein).

In another aspect, an exemplary semiconductor structure includes an air gap back-end-of-line (BEOL) interconnect structure having a plurality of wiring levels, in which a wiring level of the plurality of wiring levels includes a conductive line, two or more vias electrically connecting two or more levels of the plurality of wiring levels, and an air gap located between the two or more vias. The semiconductor structure further includes a low-k MₓSi_{y}O_{z} dielectric associated with the conductive line and the two or more vias (the “M” is a metal such as manganese or other materials disclosed herein).

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide for an improvement in Copper (Cu) diffusion barrier and Cu or other metals (e.g., Co, W, Ru, Mo, etc.) oxidation with low-to-no plasma induced damage; with good adhesion to metals; and capacitance reduction of a semiconductor structure, enabling improved reliability, such as better time dependent dielectric breakdown (TDDB); metal nano interconnects and device fabrication below 2 nm node; metal liner thickness at or below 1 nm node, or in some embodiments, elimination of the liner; and an M0/M1 dielectric spacing at or below 18 nm:
by using dense metal silicate (MₓSi_{y}O_{z}) dielectrics, such as Manganese-Silicate (MnₓSi_{y}O_{z}) dielectrics or with porous metal silicate (MₓSi_{y}O_{z}) dielectric, such as Manganese-Silicate (MnₓSi_{y}O_{z}) dielectrics with a porosity of up to 1-25%,
by using dense or porous Manganese-Silicate (MnₓSi_{y}O_{z}) interlayer dielectrics (ILDs) with Mn concentration in 0.5 to 25 atomic percentage,
by using dense or porous metal Silicate (MₓSi_{y}O_{z}) interlayer dielectrics (ILDs) such as Manganese-Silicate (MnₓSi_{y}O_{z}) interlayer dielectrics (ILDs) with low k of 3.7 to 4.2 (for dense to porous dielectric) and a high modulus of greater than or equal to 65 or 75 GPa,
by using ultrathin (2-20 nm or 2-30 nm) metal silicate (MₓSi_{y}O_{z}) interlayer dielectrics (ILDs), such as Manganese-Silicate (MnₓSi_{y}O_{z}), as interlayer dielectrics (ILDs), cap, and/or dielectric liner,
by exerting compressive stress, improving multi-layer interlayer dielectric (ILD)/ ap structure for cracking resistance,
by utilizing manganese precursors,

by forming an air gap back-end-of-line (BEOL) interconnect structure with chemical vapor deposition/atomic layer deposition (CVD/ALD) Manganese-Silicate (MnₓSi_{y}O_{z}) interlayer dielectrics (ILDs),
by utilizing a reactive ion etching (RIE) patterning structure with low k interlayer dielectric (ILD) with substrative metal RIE interconnect fabrication,
by forming a non-air gap back-end-of-line (BEOL) interconnect structure with CVD/ALD metal silicate (MₓSi_{y}O_{z}) interlayer dielectrics (ILDs), such as Manganese-Silicate (MnₓSi_{y}O_{z}) interlayer dielectrics (ILDs), and/or
by utilizing a single and/or dual damascene interconnect structure.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 shows an embodiment of a back-end-of-line (BEOL) interconnect structure, according to an aspect of the invention;

FIGS. 2A-2D show an exemplary dual damascene process for manufacturing a back-end-of-line (BEOL) interconnect structure, according to an aspect of the invention;

FIG. 2E shows an example image of an exemplary dual damascene formed back-end-of-line (BEOL) interconnect structure according to the process of FIGS. 2A-2D, according to an aspect of the invention;

FIGS. 3A-3C show an exemplary single damascene process for manufacturing a back-end-of-line (BEOL) interconnect structure, according to an aspect of the invention;

FIG. 3D shows an example image of an exemplary single damascene formed back-end-of-line (BEOL) interconnect structure according to the process of FIG. 3A-3C, according to an aspect of the invention;

FIGS. 3E-3G show an exemplary single damascene process for manufacturing a back-end-of-line (BEOL) interconnect structure, according to an aspect of the invention;

FIG. 4 shows an embodiment of an air gap back-end-of-line (BEOL) interconnect structure, according to an aspect of the invention;

FIGS. 5A-5G show an exemplary process for manufacturing an air gap back-end-of-line (BEOL) interconnect structure according to the embodiment of FIG. 4, according to an aspect of the invention;

FIG. 5H shows an example image of an exemplary air gap back-end-of-line (BEOL) interconnect structure according to the process of FIGS. 5A-5G, according to an aspect of the invention;

FIGS. 6A-6E show an exemplary process for manufacturing an air gap back-end-of-line (BEOL) interconnect structure according to the embodiment of FIG. 4, according to an aspect of the invention;

FIG. 6F shows an example image of an exemplary air gap back-end-of-line (BEOL) interconnect structure according to the process of FIGS. 6A-6E, according to an aspect of the invention;

FIG. 7 shows an embodiment of a non-air gap back-end-of-line (BEOL) interconnect structure, according to an aspect of the invention;

FIGS. 8A-8D show an exemplary process for manufacturing a non-air gap back-end-of-line (BEOL) interconnect structure according to the embodiment of FIG. 7, according to an aspect of the invention;

FIGS. 9A-9E show an exemplary process for manufacturing a non-air gap back-end-of-line (BEOL) interconnect structure according to the embodiment of FIG. 7, according to an aspect of the invention; and

FIG. 9F shows an example image of an exemplary non-air gap back-end-of-line (BEOL) interconnect structure according to the process of FIGS. 9A-9E, according to an aspect of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

One or more embodiments advantageously provide an interconnect structure utilizing low-k dielectrics in which separations between adjacent metal features can be minimized without increasing TDDB and jeopardizing reliability. Indeed, one or more embodiments advantageously provide a semiconductor structure with an ultrathin, low dielectric constant (low-k) metal silicate (MₓSi_{y}O_{z} where M is a metal) dielectric with a high modulus, density, and/or porosity. More specifically, a back-end-of-line (BEOL) interconnect structure of a semiconductor structure can be formed utilizing a MₓSi_{y}O_{z} dielectric in which a single and/or dual damascene process, a reactive ion etching (RIE) patterning with subtractive metal RIE interconnect process, a combination thereof, and/or other processes known in the art, can be used to fabricate an air gap BEOL interconnect structure, a non-air gap BEOL interconnect structure, or a combination thereof. The M of the low-k MₓSi_{y}O_{z} dielectric is a metal that can include Manganese (Mn), Magnesium (Mg), Aluminum (Al), Cobalt (Co), Tungsten (W) or Molybdenum (Mo). Typically, throughout the following descriptions, an MnₓSi_{y}O_{z} dielectric will be described; however, it is to be understood that in some embodiments the Mn can be interchangeable with Mg, Al, Co, W, or Mo. BEOL interconnect structures utilizing such MₓSi_{y}O_{z} dielectrics can exhibit improvements in diffusion barrier, oxidization, and time dependent dielectric breakdown (TDDB) while supporting reductions in a separation between (i.e., pitch of) adjacent metal nano features down to and below 18 nm pitches, enabling for a reduction in overall size of the semiconductors in various sub- 2 nm nodes with improved long-term reliability.

As used herein, the term “interconnect” refers to a conductive structure designed to transmit electrical signals (e.g., current) from one location to another location within the semiconductor structure. Interconnect structures disclosed herein can be incorporated into an electrical device. For example, semiconductor structures incorporated with an electrical device can include interconnect structures located in integrated circuit chips (ICs). Such ICs can be integrated with other ICs, discrete circuits, and/or other electrical devices as part of an intermediate and/or end product, including but not limited to AI device applications.

An MnₓSi_{y}O_{z} dielectric (or, in some embodiments, MgₓSi_{y}O_{z}, AlₓSi_{y}O_{z}, CoₓSi_{y}O_{z}, WₓSi_{y}O_{z}, or MoₓSi_{y}O_{z} dielectric) can be used as an interlayer dielectric (ILD), a liner, and/or a cap within the BEOL interconnect structure. The liner can be a metal diffusion/oxidation barrier with a thickness that can be as small as 2 nm or less. In some embodiments, the dense or porous MnₓSi_{y}O_{z} dielectric can have a low-k of 3.7-4.2, a high modulus (i.e., Young's modulus, E) equal to or greater than 65 gigapascals (GPa), or in some instances greater than 75 GPa, and/or a porosity of 1-25% for porous film, or in some instances, a dense film (0% porosity) is employed—thus, generally, a porosity of 0-25%. In some preferred embodiments, an ILD and/or cap material can include 1-15% porosity. Additionally, the MnₓSi_{y}O_{z} dielectric can include 1-25% Mn, with less than 33% Si and less than 60% O. In some preferred embodiments, the MnₓSi_{y}O_{z} dielectric can include 1-10% Mn. Further, in some embodiments, an MₓSi_{y}O_{z} dielectric can include 0.5-10 atomic % M (exemplary materials for “M” are set forth elsewhere herein). Further, the MnₓSi_{y}O_{z} dielectric can exert a compressive stress that compensates for the regular tensile stress of a cap film which can improve a multi-layer ILD and/or a dielectric cap structure for cracking resistance. That is, the MnₓSi_{y}O_{z} dielectric (or, in some embodiments, MgₓSi_{y}O_{z}, AlₓSi_{y}O_{z}, CoₓSi_{y}O_{z}, WₓSi_{y}O_{z}, or MoₓSi_{y}O_{z} dielectric) can exert a compressive stress on each ILD, balancing a stress force in each metal/cap/ILD layer, reducing conventional bowing that can typically be observed in conventional SiCOH ILD/SiCN cap structures. In general, the typical thicker SiCOH/pSiCOH dielectric ILDs with low modulus (less than 12 GPa and UV cured SiCN) cap that are used in current semiconductor devices have tensile stress and cause significant wafer bowing stress, and then subsequent cracking, on sub-10 nm node BEOL multilevel metal interconnect structures. The Compressive Metal silicates ILD in accordance with aspects of the invention have good compressive stress with a high modulus of greater than or equal to 65 GPa and balance out the tensile stress of the interconnect metal and tensile-stressed cap, thus improving the cracking resistance of the overall dielectric/metal/cap multilayer structure. In some embodiments, the MnₓSi_{y}O_{z} dielectric (or, in some embodiments, MgₓSi_{y}O_{z}, AlₓSi_{y}O_{z}, CoₓSi_{y}O_{z}, WₓSi_{y}O_{z}, or MoₓSi_{y}O_{z} dielectric) can surround conductive lines of the BEOL interconnect structure, can be located below the conductive lines with one or more vias of the BEOL interconnect structure, or can both surround the conductive lines and be located below with the one or move vias of the BEOL interconnect structure. The MnₓSi_{y}O_{z} dielectric (or, in some embodiments, MgₓSi_{y}O_{z}, AlₓSi_{y}O_{z}, CoₓSi_{y}O_{z}, WₓSi_{y}O_{z}, or MoₓSi_{y}O_{z} dielectric) thus can cover, or cover in part, one or more levels of the BEOL interconnect structure.

In some embodiments, MₓSi_{y}O_{z} dielectrics, such as the MnₓSi_{y}O_{z} dielectric, can further include Nitrogen (MnₓSi_{y}O_{z}Nᵥ) or Nitrogen and Carbon (MnₓSi_{y}O_{z}NᵥC_{w}). During typical manufacturing processes of a semiconductor structure, Carbon (C) within a dielectric can be removed using a plasma etch process. Beneficially, since MnₓSi_{y}O_{z}NᵥC_{w}, MnₓSi_{y}O_{z}Nᵥ, and MnₓSi_{y}O_{z} dielectrics include little to no C, minimal to no plasma induced damage can be observed during the manufacturing process. The Nitrogen and Carbon incorporated in the MnₓSi_{y}O_{z} are normally less than 10 atomic % to maintain lower k, high modulus, and minimum plasma induced damage.

Further, in some embodiments, such as those referenced in the following descriptions, conductive lines and vias of the BEOL interconnect structure can include metals such as, Copper (Cu), Ruthenium (Ru), Rhodium (Rh), Cobalt (Co), Tungsten (W), Copper-Aluminum (CuAl), Iridium (Ir), Molybdenum (Mo) or can be any combination thereof. Typically, performance of the semiconductor structure can often be seen as best with a combination of Cu and low-k dielectrics. In some cases, low-k dielectrics can be more advantageous when they are highly porous as high porosity can absorb moisture. However, Cu diffusion and moisture leakage into the pores of the dielectric can increase both the dielectric constant (k) and a leakage current between metal features of the device, resulting in a potential electrical breakdown of the semiconductor structure. As such, a combination of low-k dielectrics with high porosity and Cu interconnects can be fragile against oxygen and moisture. However, MₓSi_{y}O_{z} dielectrics, such as MnₓSi_{y}O_{z} dielectrics, can function as a barrier to oxygen and moisture and can aid in prevention of undesirable metal diffusion, moisture absorption, oxidation, and device damage. Further, a metal liner, such as Tantalum (Ta), Tantalum-Nitride (TaN), Cobalt (Co), or Tungsten (W), can optionally be formed between the MnₓSi_{y}O_{z} dielectrics and conductive lines and vias of the BEOL interconnect structure to further enhance protection against undesirable metal diffusion, moisture absorption, oxidation, and damage to the device. In some embodiments, when using Cu for conductive lines and vias, a benefit can be seen from the addition of the metal liner. However, other metals such as Ru, Rh, Co, W, CuAl, Ir, and Mo often fare better and benefits of the addition of the metal liner may be minimal to none and thus some embodiments may not include the metal liner between the MnₓSi_{y}O_{z} dielectrics and conductive lines and vias of the BEOL interconnect structure.

In some embodiments, for example with metal silicate such as MnₓSi_{y}O_{z}, a dielectric cap can be formed over a first level of the BEOL interconnect structure, separating the first interconnect level from a second level. The MnₓSi_{y}O_{z} dielectric cap can serve as an insulator for the first level and can improve interconnect reliability and reduce potential for metal diffusion into the ILD of the second level. The MₓSi_{y}O_{z} ILD, liner, and/or cap can be deposited using known deposition techniques, such as, for example, Chemical Vapor Deposition (CVD), Plasma Enhanced Chemical Vapor Deposition (PECVD), Plasma Enhanced Atomic Layer Deposition (PE ALD), or Flowable Chemical Vapor Deposition (FCVD), to name a few. In some embodiments, deposition can be done with precursors such as Mn Amidinate (such as manganese (II) bis (N,N′-diisopropylpentamidinate) or Mn Tris (2,2,6,6-tetramethyl-3,5-heptanedionato) manganese (III) or Cyclopentadienyl manganese tricarbonyl and +H₂O/O2 and Carbosilane/Organosilicon reactants like tetramethyl Silane and similar groups. The thickness of the MₓSi_{y}O_{z} dielectric can vary depending on the application and can have a thickness of 2-20 nm (or even less than 2 nm), or in some instances, 2-30 nm (or even less than 2 nm), though embodiments are not so limited.

Additionally, certain interconnect metals, such as Cu, can form rather weak bonds to some dielectrics that include metal oxides and nitrides. Having a weak adhesion between the interconnect and such dielectrics can lead to failure of the interconnect. For example, an open circuit can form where a metal line breaks after electric current flows through a weak interface between the metal line and an overlying dielectric layer. Additionally, for example, a short circuit between adjacent metal lines can form after an electromigration of one or more of the metal lines. Thus, in some previous approaches, adhesives can be added to bond interconnect metals to dielectrics. However, MₓSi_{y}O_{z} dielectrics, such as MnₓSi_{y}O_{z} dielectrics, can have a good adhesion to metals such as Cu, Ru, Rh, Co, W, CuAl, Ir, and Mo, thus minimizing weak bonds that can cause open and short circuits and reducing uses of adhesive layers within a semiconductor structure. Thus, MnₓSi_{y}O_{z} dielectrics can make an advantageous option for BEOL interconnect structures.

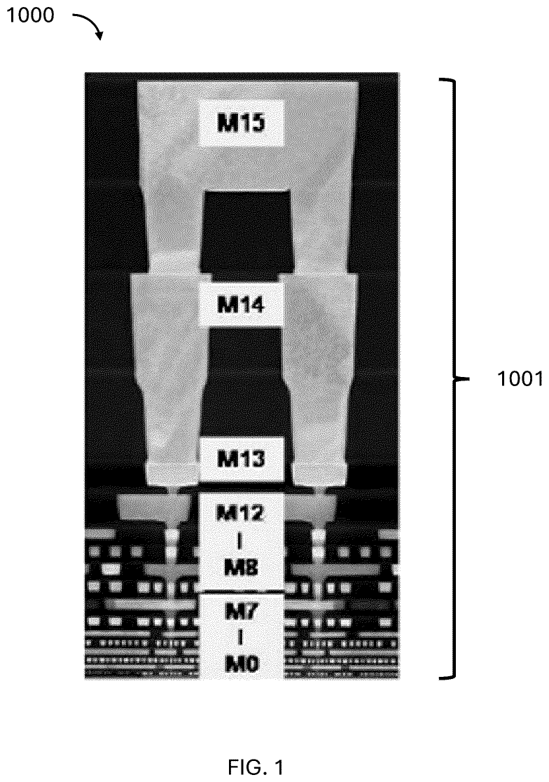

Referring now to FIG. 1, there is shown an exemplary semiconductor structure 1000 including a back-end-of-line (BEOL) interconnect structure 1001 having a plurality of wiring levels M0-M15. Though FIG. 1 illustrates a plurality of wiring levels of M0-M15, examples are not so limited and any number of wiring levels known in the art (including one wiring level), can be contemplated. As is illustrated in further detail herein, the plurality of wiring levels M0-M15 can include conductive lines, a low-k Manganese-Silicate (MnₓSi_{y}O_{z}), and one or more vias electrically connecting two or more levels of the plurality of wiring levels. Although FIG. 1-FIG. 9F illustrate a MnₓSi_{y}O_{z} dielectric, in some embodiments, it can be contemplated that other dielectrics, such as, MgₓSi_{y}O_{z}, AlₓSi_{y}O_{z}, CoₓSi_{y}O_{z}, WₓSi_{y}O_{z}, or MoₓSi_{y}O_{z} can be used.

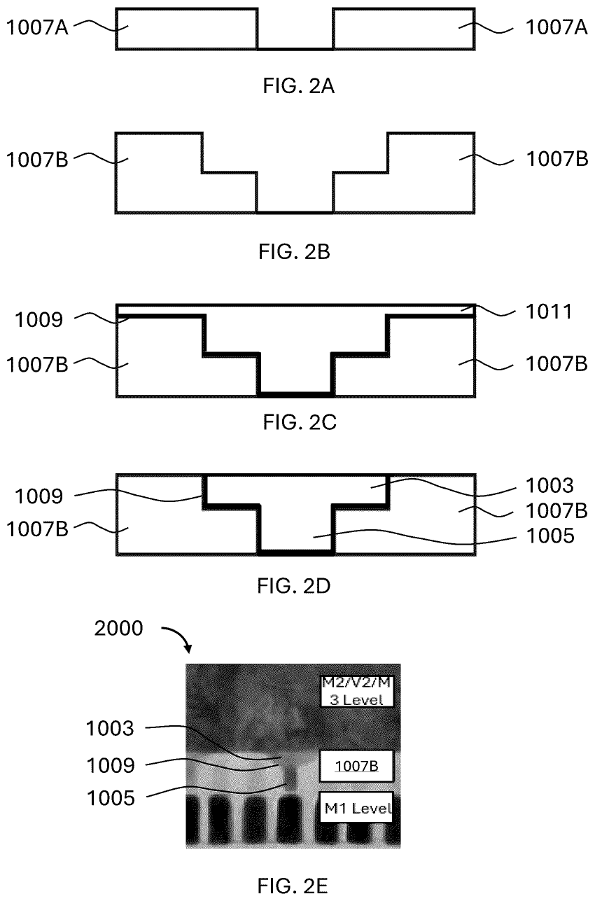

FIGS. 2A-2D illustrate, according to some aspects, a method for manufacturing a back-end-of-line (BEOL) interconnect structure of a semiconductor structure utilizing a dual damascene process. As is well known in the art, a BEOL interconnect structure fabrication process can include depositing and patterning successive levels of a dielectric and a metallic material forming a wiring interconnect network of electrical connections. For example, in some embodiments, as shown in FIG. 2A, an MnₓSi_{y}O_{z} dielectric 1007A can be deposited. As an example, the MnₓSi_{y}O_{z} dielectric 1007A can be deposited on a substrate (not shown) of a semiconductor structure. Utilizing processes known in the art, such as, lithography and RIE patterning processes, a portion of the MnₓSi_{y}O_{z} dielectric 1007A (e.g., center portion as shown in FIG. 2A) can be etched away to form an opening or a profile for a via (e.g., via 1005 as shown in FIG. 2D).

Turning now to FIG. 2B, additional MnₓSi_{y}O_{z} dielectric can be deposited on the etched MnₓSi_{y}O_{z} dielectric 1007A of FIG. 2A to form a thicker dielectric 1007B, and utilizing processes known in the art, such as, lithography and RIE patterning processes, a portion of the MnₓSi_{y}O_{z} dielectric (e.g., the larger center portion as shown in FIG. 2B) can be etched away to form an opening or a profile for a conductive line (e.g., conductive line 1003 as shown in FIG. 2D). As shown in FIG. 2C, a metal liner 1009 can be deposited over the thicker dielectric 1007B. The metal liner 1009 can have a thickness down to 2 nm. In some embodiments, the metal liner 1009 can have a thickness of 1 nm or less, though examples are not so limited. Additionally, in some embodiments, the metal liner 1009 can be optional depending on the composition of the metal via and conductive line (such as with Cu as previously stated) and can include metals known in the art, such as, Tantalum (Ta), Tantalum-Nitride (TaN), Cobalt (Co), or Tungsten (W). Further, metal 1011, such as the Copper (Cu), Ruthenium (Ru), Rhodium (Rh), Cobalt (Co), Tungsten (W), Copper-Aluminum (CuAl), Iridium (Ir), or Molybdenum (Mo) metals previously described, can be deposited over the metal liner 1009, filling the openings that created the via and the conductive line profiles.

Excess metal 1011 and metal liner 1009 can be removed, as shown in FIG. 2D. Further, chemical mechanical polishing (CMP) and planarization processes can be performed on the interconnect structure. As such, as shown in FIG. 2D, a via 1005 and a conductive line 1003 can be formed within the thicker dielectric 1007B and, optionally, separated from the thicker dielectric 1007B by the metal liner 1009. As such, formation of the via and the conductive line profiles can occur at separate times while the metallization of the via 1005 and the conductive line 1003 can be formed at the same time.

FIG. 2E illustrates an example image of an exemplary BEOL interconnect structure 2000 including a dual damascene formed conductive line 1003 and via 1005 structure having a metal liner 1009 that separates the conductive line 1003 and via 1005 from the thicker dielectric 1007B. In some embodiments, the thicker dielectric 1007B can be an interlayer dielectric (ILD) of the BEOL interconnect structure 2000. Accordingly, formation of the via 1005 and the conductive line 1003 of a BEOL interconnect structure 2000 can utilize the dual damascene process, though examples are not so limited.

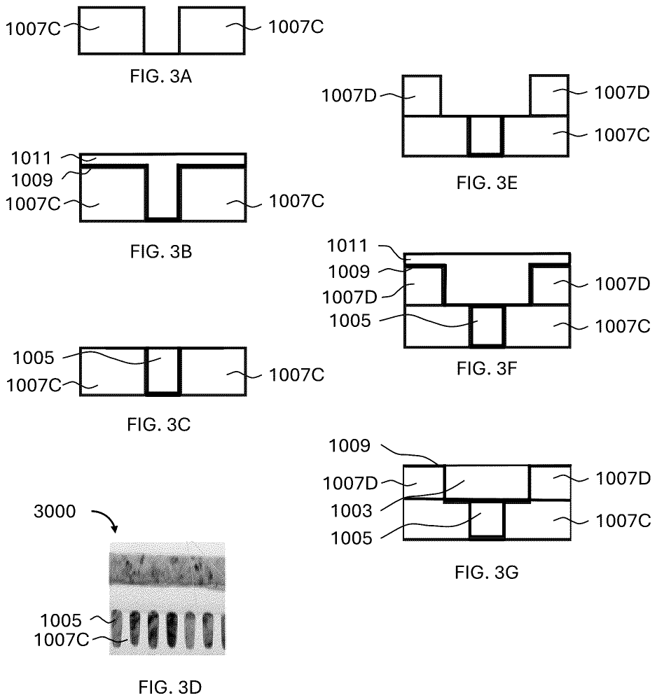

FIGS. 3A-3C and 3E-3F illustrate, according to some aspects, a method for manufacturing a back-end-of-line (BEOL) interconnect structure of a semiconductor structure utilizing a single damascene process. In some embodiments, as shown in FIG. 3A, an MnₓSi_{y}O_{z} dielectric 1007C can be deposited. The MnₓSi_{y}O_{z} dielectric 1007C can be deposited on a substrate (not shown) of a semiconductor structure. Utilizing processes known in the art, such as, lithography and RIE patterning processes, a portion of the MnₓSi_{y}O_{z} dielectric 1007C (e.g., center portion as shown in FIG. 3A) can be etched away to form an opening or a profile for a via (e.g., via 1005 as shown in FIG. 3C).

Turning now to FIG. 3B, a metal liner 1009 can be deposited over the MnₓSi_{y}O_{z} dielectric 1007C. The metal liner 1009 can have a thickness of 1 nm or less, in some examples. Additionally, in some embodiments, the metal liner 1009 can be optional depending on the composition of the metal via and can include metals known in the art, such as, Tantalum (Ta), Tantalum-Nitride (TaN), Cobalt (Co), or Tungsten (W). Further, metal 1011, such as those previously described (i.e., Cu, Ru, Rh, Co, W, CuAl, Ir, or Mo), can be deposited over the metal liner 1009, filling the opening that created the via profile. Excess metal 1011 and metal liner 1009 can be removed, as shown in FIG. 3C. Further, chemical mechanical polishing (CMP) and planarization processes can be performed on the etched structure. As such, as shown in FIG. 3C, a via 1005 can be formed within an MnₓSi_{y}O_{z} dielectric 1007C and optionally separated from the MnₓSi_{y}O_{z} dielectric 1007C by the metal liner 1009.

FIG. 3D illustrates an example image of an exemplary BEOL interconnect structure 3000 including a plurality of single damascene formed vias 1005 separated by MnₓSi_{y}O_{z} dielectric 1007C. Accordingly, the MnₓSi_{y}O_{z} dielectric 1007C can be an interlayer dielectric (ILD) of the BEOL interconnect structure 3000.

Continuing with FIG. 3E, an additional MnₓSi_{y}O_{z} dielectric 1007D can be deposited on the CMP and planarized via 1005 and MnₓSi_{y}O_{z} dielectric 1007C of FIG. 3C, and, utilizing processes known in the art, such as, lithography and RIE patterning processes, a portion of the MnₓSi_{y}O_{z} dielectric 1007D (e.g., center portion as shown in FIG. 3E) can be etched away to form an opening or a profile for a conductive line.

Turning now to FIG. 3F, a metal liner 1009 can be deposited over the additional MnₓSi_{y}O_{z} dielectric 1007D and the via 1005. The metal liner 1009 can have a thickness of 1 nm or less, in some examples. Additionally, in some embodiments, the metal liner 1009 can be optional depending on the composition of the metal conductive line 1003 and can include metals known in the art, such as, Ta, TaN, Co, or W. Further, metal 1011 such as, Cu, Ru, Rh, Co, W, CuAl, Ir, or Mo can be deposited over the metal liner 1009, filling the opening that created the conductive line profile.

Excess metal 1011 and metal liner 1009 can be removed, as shown in FIG. 3G. Further, chemical mechanical polishing (CMP) and planarization processes can be performed on the etched structure. As such, as shown in FIG. 3G, a conductive line 1003 can be formed above the via 1005 and within the additional MnₓSi_{y}O_{z} dielectric 1007D. Further, the conductive line 1003 can optionally be separated from the via 1005 and the MnₓSi_{y}O_{z} dielectric 1007C, 1007D by the metal liner 1009. As such, formation of the via profile and the conductive line profile can occur separately and the metallization of the conductive line 1003 and the via 1005 can also occur separately. Accordingly, formation of the via 1005 and the conductive line 1003 of a BEOL interconnect structure can utilize a single damascene process, though examples are not so limited.

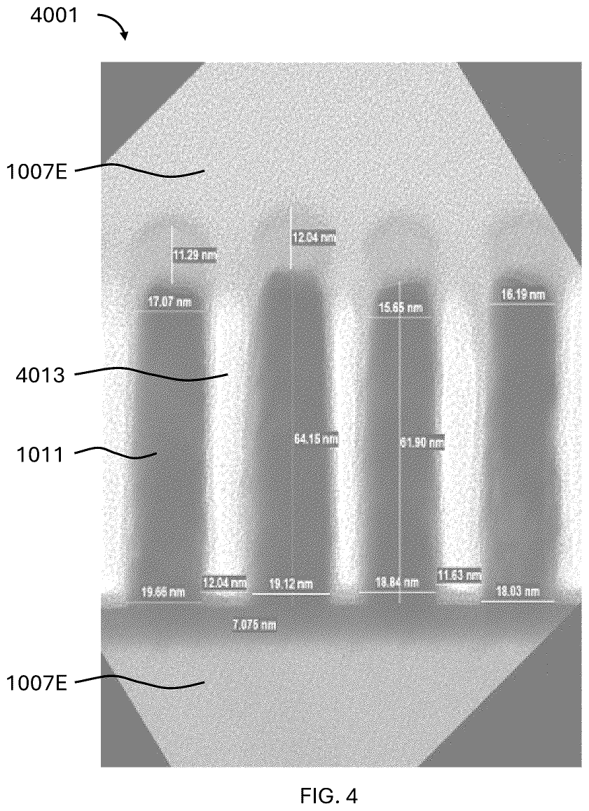

FIG. 4 illustrates an exemplary back-end-of-line (BEOL) interconnect structure 4001 including an air gap 4013 located between metal 1011 interconnects of the BEOL interconnect structure 4001. In some embodiments, the air gap 4013 can be formed between metal 1011 wires with a narrow pitch at and below 18 nm, though examples are not so limited. Further, in some embodiments, the BEOL interconnect structure 4001 can include an MnₓSi_{y}O_{z} dielectric 1007E. The MnₓSi_{y}O_{z} dielectric 1007E can be an interlayer dielectric (ILD), a dielectric liner, and/or a dielectric cap, as described in further detail herein.

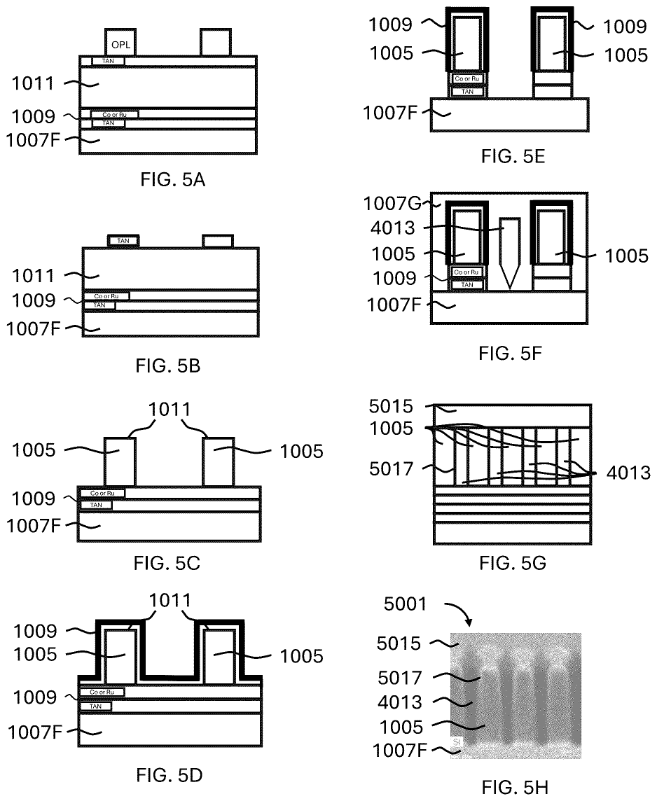

FIGS. 5A-5G illustrate, according to some aspects, a method for manufacturing an air gap back-end-of-line (BEOL) interconnect structure of a semiconductor structure. Turning to FIG. 5A, a MnₓSi_{y}O_{z} dielectric 1007F can be deposited over a substrate (not shown) of a semiconductor structure or a lower level of a BEOL interconnect structure of the semiconductor structure (not shown). A metal 1011, such as those previously described (i.e., Cu, Ru, Rh, Co, W, CuAl, Ir, or Mo), can be deposited over the MnₓSi_{y}O_{z} dielectric 1007F.

In some embodiments, a metal liner 1009 can be deposited prior to the MnₓSi_{y}O_{z} dielectric 1007F. As previously described, the composition of the MnₓSi_{y}O_{z} dielectric 1007F provides for good adhesion between the MnₓSi_{y}O_{z} dielectric 1007F and the metal 1011. Having a good adhesion to metals 1011, such as Cu, Ru, Rh, Co, W, CuAl, Ir, and Mo can minimize an occurrence of weak bonds between the MnₓSi_{y}O_{z} dielectric 1007F and the metal 1011 which could cause open and short circuits and can reduce uses of adhesive layers within the semiconductor structure. Further, MnₓSi_{y}O_{z} dielectrics can function as a barrier to oxygen and moisture and can aid in prevention of undesirable metal diffusion, moisture absorption, oxidation, and device damage. As such, the metal liner 1009 can be optional and utilized dependent upon aspects, including but not limited to composition of the metal 1011 (e.g., in some cases where Cu is utilized) of the BEOL interconnect structure, potential electrical field between interconnections, etc. As shown in FIG. 5A, a barrier (e.g., TaN) can be deposited over the metal 1011 and an organic planarization layer OPL can be formed over the barrier. The OPL can create a standard patterning for formation of vias (e.g., via 1005 as shown in FIG. 5C), as will be described in further detail.

Turning to FIG. 5B, utilizing a hard mask reactive ion etching (HM RIE) patterning process known in the art, a portion of the barrier and the OPL can be removed. As illustrated in FIG. 5C, in some embodiments, an HM removal process can then be performed. Accordingly, a portion of the metal 1011 can be etched away to form vias 1005 and the remaining barrier can be removed. Turning now to FIG. 5D, an addition to the metal liner 1009 can be deposited over the vias 1005 and the original portion of the metal liner 1009, though examples are not so limited and the addition of the metal liner 1009 can be optional and based on a multitude variables, such as composition of the metal 1011, pitch between vias 1005, thickness of the vias 1005, etc. A further RIE process can be performed, and a portion of the metal liner 1009 can be removed, leaving metal liner 1009 covering the vias 1005 and located between the vias 1005 and the MnₓSi_{y}O_{z} dielectric 1007F as illustrated in FIG. 5E.

As illustrated in FIG. 5F, additional MnₓSi_{y}O_{z} dielectric 1007G can be deposited over the vias 1005, the optional metal liner 1009, and the original portion of the MnₓSi_{y}O_{z} dielectric 1007F. An air gap 4013 can be formed in the MnₓSi_{y}O_{z} dielectric 1007G between the vias 1005. In some embodiments, the air gap 4013 can be formed using a pinch off deposition process, though examples are not so limited. Further, in some embodiments, the pitch between air gaps 4013 can be approximately 28 nm, though examples are not so limiting. Further, chemical mechanical polishing (CMP) and planarization processes can be performed on the interconnect structure.

FIG. 5G illustrates a series of vias 1005 separated by air gaps 4013. In some embodiments, the MnₓSi_{y}O_{z} dielectric can be, in part, located between each via 1005 and each air gap 4013 forming a MnₓSi_{y}O_{z} dielectric liner 5017. Further, the MnₓSi_{y}O_{z} dielectric can be deposited over the vias 1005 and the air gaps 4013 forming a MnₓSi_{y}O_{z} dielectric cap 5015.

FIG. 5H illustrates an example image of an exemplary air gap BEOL interconnect structure 5001 including a plurality of vias 1005 having an MnₓSi_{y}O_{z} dielectric liner 5017, and separated by air gaps 4013. The vias 1005 are shown covered with an MnₓSi_{y}O_{z} dielectric cap 5015. Further, an MnₓSi_{y}O_{z} interlayer dielectric (ILD) can be located below the vias 1005 and optionally separated from the vias 1005 by a metal liner 1009.

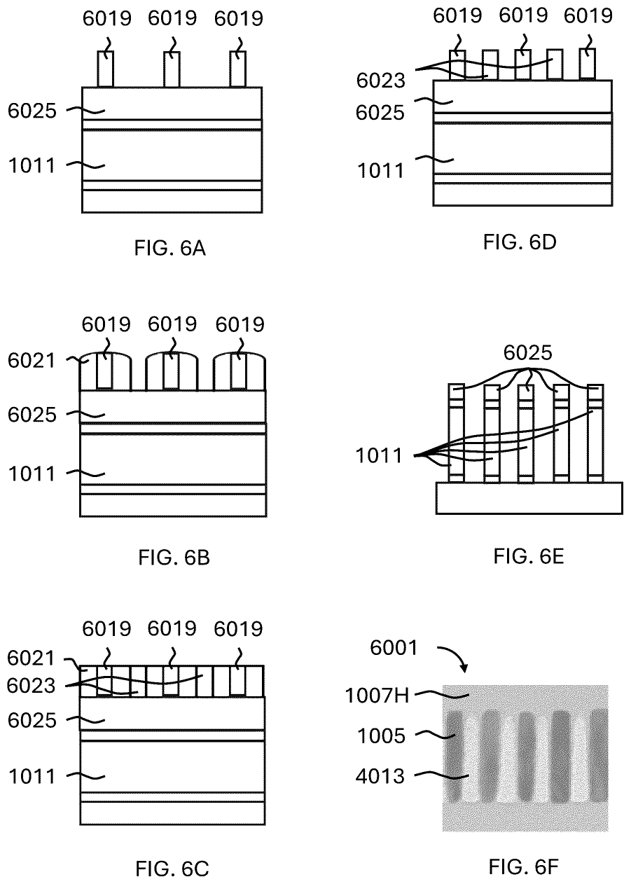

FIGS. 6A-6E illustrate, according to some aspects, a method for manufacturing an air gap back-end-of-line (BEOL) interconnect structure of a semiconductor structure. Turning to FIG. 6A, a metal 1011, such as those previously described (i.e., Cu, Ru, Rh, Co, W, CuAl, Ir, or Mo), can be deposited over a substrate of a semiconductor structure. A hard mask (HM) 6025 can be deposited over the metal 1011 and, utilizing a mandrel patterning process, a plurality of mandrels 6019 can be formed on the HM 6025.

FIG. 6B illustrates a spacer 6021 deposited around the pre-patterned mandrel 6019. A spacer 6021 can be deposited and surround each mandrel 6019, leaving an open space between each spacer 6021. As shown in FIG. 6C, a non-mandrel 6023 can be formed between each spacer 6021 filling each open space. Once the non-mandrel 6023 is formed, as illustrated in FIG. 6D, the spacers 6021 can be etched back removing a portion of each spacer 6021 between the mandrel 6019 and the non-mandrel 6023. In some embodiments, a portion of the spacer 6021 can remain on the side walls of the mandrels 6019, the non-mandrels 6023, or both. As illustrated in FIG. 6E, utilizing the mandrels 6019 and the non-mandrels 6023 as a pattern, trenches can be etched within the HM 6025 and the metal 1011 and the mandrels 6019 and the non-mandrels 6023 can be removed.

The HM 6025 can then be removed and an MnₓSi_{y}O_{z} dielectric 1007H can be deposited as shown in FIG. 6F. The MnₓSi_{y}O_{z} dielectric 1007H can be deposited utilizing processes known in the art such as Plasma Enhanced Chemical Vapor Deposition (PECVD), etc. FIG. 6F illustrates an example image of an exemplary air gap BEOL interconnect structure 6001 including a plurality of vias 1005 with the MnₓSi_{y}O_{z} dielectric 1007H deposited over the vias 1005, forming air gaps 4013 between each via 1005.

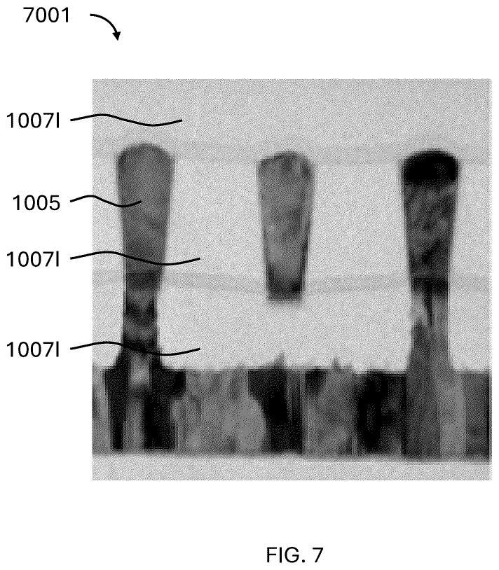

FIG. 7 illustrates an exemplary non-air gap back-end-of-line (BEOL) interconnect structure 7001 including an MnₓSi_{y}O_{z} dielectric 1007I surrounding via 1005 interconnects of the BEOL interconnect structure 7001. The MnₓSi_{y}O_{z} dielectric 1007I can be an interlayer dielectric (ILD), a dielectric liner, and/or a dielectric cap, as described in further detail herein.

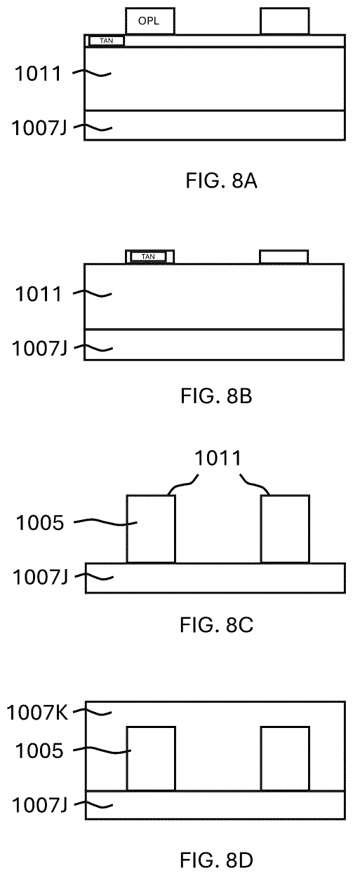

FIGS. 8A-8D illustrate, according to some aspects, a method for manufacturing a non-air gap back-end-of-line (BEOL) interconnect structure of a semiconductor structure. In some embodiments, the method can include a substrative etch process. Turning to FIG. 8A, a MnₓSi_{y}O_{z} dielectric 1007J can be deposited over a substrate (not shown) of a semiconductor structure or a lower level of a BEOL interconnect structure of the semiconductor structure (not shown). A metal 1011, such as those previously described (i.e., Cu, Ru, Rh, Co, W, CuAl, Ir, or Mo), can be deposited over the MnₓSi_{y}O_{z} dielectric 1007J.

In some embodiments, a metal liner (not shown) can be deposited between the MnₓSi_{y}O_{z} dielectric 1007J and the metal 1011, though examples are not so limited. As shown in FIG. 8A, a barrier (e.g., TaN) can be deposited over the metal 1011 and an organic planarization layer OPL can be formed over the barrier. The OPL can create a standard patterning for formation of vias (e.g., via 1005 as shown in FIG. 8C), as will be described in further detail.

Turning to FIG. 8B, utilizing a hard mask reactive ion etching (HM RIE) patterning process known in the art, a portion of the barrier and the OPL can be removed. As illustrated in FIG. 8C, in some embodiments, an HM removal process can then be performed. Accordingly, a portion of the metal 1011 can be etched away to form vias 1005 and the remaining barrier can be removed. Turning now to FIG. 8D, additional MnₓSi_{y}O_{z} dielectric 1007K can be deposited over the vias 1005 and the original portion of the MnₓSi_{y}O_{z} dielectric 1007J. In some embodiments, an addition to the metal liner (not shown) can be deposited over the vias 1005 and the original portion of the metal liner, prior to the deposition of the MnₓSi_{y}O_{z} dielectric 1007K, though examples are not so limited. Note that a MnₓSi_{y}O_{z} dielectric liner may not be included in the non-air gap interconnect structure. Further, chemical mechanical polishing (CMP) and planarization processes can be performed on the interconnect structure. FIG. 8D illustrates the vias 1005 encapsulated by the MnₓSi_{y}O_{z} dielectric 1007K, forming, at least in part, the non-air gap BEOL interconnect structure of a semiconductor structure.

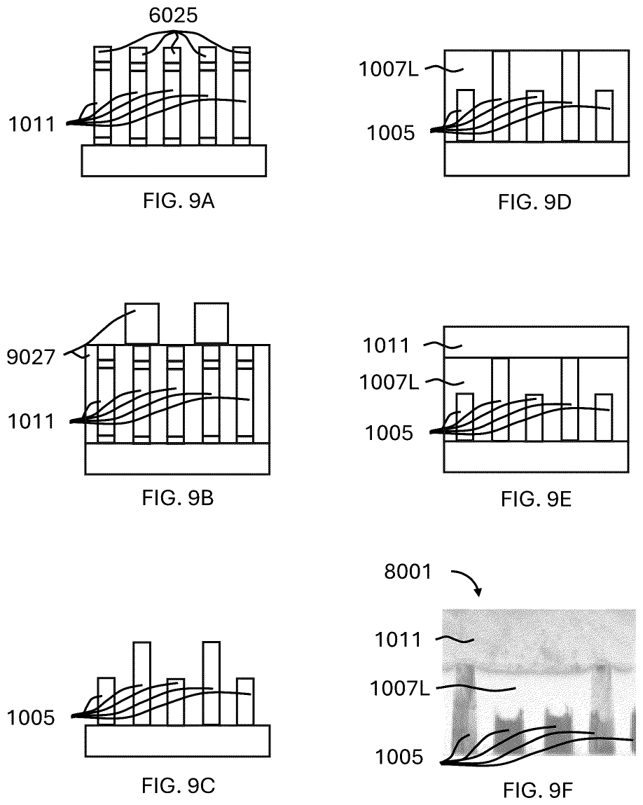

FIGS. 9A-9F illustrate, according to some aspects, a method for manufacturing a non-air gap back-end-of-line (BEOL) interconnect structure of a semiconductor structure. As previously illustrate in reference to FIGS. 6A-6D, a metal (e.g., metal 1011 as illustrated in FIG. 6A), such as Cu, Ru, Rh, Co, W, CuAl, Ir, or Mo, can be deposited over a substrate of a semiconductor structure. A hard mask (HM) (e.g., HM 6025 as illustrated in FIG. 6A) can be deposited over the metal and, utilizing a mandrel patterning process, a plurality of mandrels (e.g., mandrels 6019 as illustrated in FIG. 6A) can be formed on the HM. A spacer (e.g., spacer 6021 as illustrated in FIG. 6B) can be deposited around the pre-patterned mandrels. A spacer can be deposited and surround each mandrel, leaving an open space between each spacer. Further, a non-mandrel (e.g., non-mandrel 6023 as illustrated in FIG. 6C) can be formed between each spacer filling each open space. Once the non-mandrel is formed, the spacers can be etched back removing a portion of each spacer between the mandrel and the non-mandrel. In some embodiments, a portion of the spacer can remain on the side walls of the mandrels, the non-mandrels, or both.

Turning now to FIG. 9A, utilizing the mandrels and the non-mandrels as a pattern, trenches can be etched within the HM 6025 and the metal 1011 and the mandrels and the non-mandrels can be removed. A process for top via patterning 9027 can be implemented as illustrated in FIG. 9B. FIG. 9C illustrates a top via RIE and HM removal process. Accordingly, the top via patterning 9027 and HM 6025 can be removed and the metal 1011 can be etched forming vias 1005. As an example, FIG. 9C illustrates two lengths of vias 1005, though examples are not so limited. An MnₓSi_{y}O_{z} dielectric 1007L can be deposited as shown in FIG. 9D. The MnₓSi_{y}O_{z} dielectric 1007L can be an interlayer dielectric (ILD) which fills in an area between the vias 1005. The MnₓSi_{y}O_{z} dielectric 1007L can be deposited using process known in the art, such as a Chemical Vapor Deposition (CVD), an Atomic Layer Deposition (ALD), etc. Further, chemical mechanical polishing (CMP) and planarization processes can be performed on the interconnect structure, exposing a top surface of the longest vias 1005.

A next level of the non-air gap BEOL interconnect structure of the semiconductor structure can be formed on the surface of the longest vias 1005 as shown in FIG. 9E. That is, metal 1011 can be deposited over the MnₓSi_{y}O_{z} dielectric 1007L and the vias 1005 forming a conductive line of the non-air gap BEOL interconnect structure.

FIG. 9F illustrates an example image of an exemplary non-air gap BEOL interconnect structure 8001. The BEOL interconnect structure 8001 including a plurality of vias 1005 surrounded by an MnₓSi_{y}O_{z} dielectric 1007L and a metal 1011 deposited over the MnₓSi_{y}O_{z} dielectric 1007L and the vias 1005 to form a conductive line of the non-air gap BEOL interconnect structure.

Thus, as illustrated a BEOL interconnect structure of a semiconductor structure can be formed utilizing a MnₓSi_{y}O_{z} dielectric in which a single and/or dual damascene process, a reactive ion etching (RIE) patterning with subtractive metal RIE interconnect process, a combination thereof, and/or other processes known in the art, can be used to fabricate an air gap BEOL interconnect structure, a non-air gap BEOL interconnect structure, or a combination thereof.

Semiconductor device manufacturing includes various steps of device patterning processes. For example, the manufacturing of a semiconductor chip can start with, for example, a plurality of CAD (computer aided design) generated device patterns, which is then followed by effort to replicate these device patterns in a substrate. The replication process can involve the use of various exposing techniques and a variety of subtractive (etching) and/or additive (deposition) material processing procedures. For example, in a photolithographic process, a layer of photo-resist material can first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) can experience some changes in their solubility to certain solutions. The photo-resist can then be developed in a developer solution, thereby removing the non-irradiated (in a negative resist) or irradiated (in a positive resist) portions of the resist layer, to create a photo-resist pattern or photo-mask. The photo-resist pattern or photo-mask can subsequently be copied or transferred to the substrate underneath the photo-resist pattern.

There are numerous techniques used by those skilled in the art to remove material at various stages of creating a semiconductor structure. As used herein, these processes are referred to generically as “etching.” For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1 ) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method can utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Exemplary semiconductor structures disclosed herein can include, for example, structures suitable for use in nano-electronic and/or artificial intelligence (AI) device fabrication. Furthermore, one or more exemplary techniques can be used, for example, for forming a semiconductor structure included in nano-electronics devices such as for logic, memory, and/or integrated packaging applications. Exemplary semiconductor structures disclosed herein can further include, for example, multilayer logic devices, memories, and integrated logic/memories for AI and/or telecommunications and the like. In some cases, a semiconductor structure includes the use of MnₓSi_{y}O_{z} high performance ILD in opto-electric telecommunication and packaging of nano devices. In yet further aspects, the MnₓSi_{y}O_{z} and MnₓN_{y}Si_{z}O_{w} materials can be considered generally as MₓSi_{y}O_{z} or MₓN_{y}Si_{z}O_{w} where the M=metals such as Mn, Mg, Al, Co, W, Mo at low doped (0.5-10 atomic percentage) concentration, used as ILD and/or cap/etch stop layer(s) with similar material performance in semiconductor structures and devices as discussed elsewhere herein.

Given the discussion thus far, it will be appreciated that in one aspect, an exemplary semiconductor structure 1000 includes a back-end-of-line (BEOL) interconnect structure 1001, 7001, 8001 having a plurality of wiring levels M0-M15, in which a wiring level of the plurality of wiring levels M0-M15 includes a conductive line 1003 and two or more vias 1005 electrically connecting two or more levels of the plurality of wiring levels M0-M15, and a low-k MₓSi_{y}O_{z} dielectric associated with the conductive line 1003 and the two or more vias 1005, where M is a metal. Note that as used herein, including the claims, “MnₓSi_{y}O_{z}” does not preclude the presence of other elements such that, unless stated to be “pure MnₓSi_{y}O_{z},” MnₓSi_{y}O_{z}Nᵥ and/or MnₓSi_{y}O_{z}NᵥC_{w} are included in MnₓSi_{y}O_{z}. Similarly, note that as used herein, including the claims, “MₓSi_{y}O_{z}” does not preclude the presence of other elements such that, unless stated to be “pure MₓSi_{y}O_{z},” MₓSi_{y}O_{z}Nᵥ and/or MₓSi_{y}O_{z}NᵥC_{w} are included in MₓSi_{y}O_{z}. Exemplary materials for “M” are presented elsewhere herein.

The “M” in the low-k MₓSi_{y}O_{z} dielectric can, in some cases, be Mn and the low-k MₓSi_{y}O_{z} dielectric accordingly can be low-k Manganese-Silicate (MnₓSi_{y}O_{z}) dielectric. M can be other materials in other cases as noted herein (e.g., Magnesium (Mg); Aluminum (Al); Cobalt (Co); Tungsten (W); and Molybdenum (Mo)).

Optionally, the conductive line 1003 and the two or more vias 1005 can be selected from the group including Copper (Cu), Ruthenium (Ru), Rhodium (Rh), Cobalt (Co), Tungsten (W), Copper-Aluminum (CuAl), Iridium (Ir), and Molybdenum (Mo).

Further, optionally, the low-k MnₓSi_{y}O_{z} dielectric can include 1-10% Manganese (Mn), less than 33% Silicon (Si), and less than 60% Oxygen (O). In further options, the low-k MnₓSi_{y}O_{z} dielectric can have a modulus equal to or greater than 75 GPa, a low-k value range of 3.7-4.2, a porosity of 0-25%, or any combination thereof.

Further, optionally, the low-k MnₓSi_{y}O_{z} dielectric can have a thickness equal to or less than 20 nm. In still further options, a pitch between the two or more vias 1005 can be equal to or less than 18 nm.

Optionally, the low-k MnₓSi_{y}O_{z} dielectric can further include Nitrogen (MnₓSi_{y}O_{z}Nᵥ) or Nitrogen and Carbon (MnₓSi_{y}O_{z}NᵥC_{w}).

In further options, the low-k MnₓSi_{y}O_{z} dielectric can be a low-k MnₓSi_{y}O_{z} dielectric cap 5015.

Optionally, the low-k MnₓSi_{y}O_{z} dielectric can be a low-k MnₓSi_{y}O_{z} interlayer dielectric (ILD) that surrounds the conductive line 1003 of the BEOL interconnect structure 1001, 7001, 8001. In further options, the low-k MnₓSi_{y}O_{z} dielectric can be a low-k MnₓSi_{y}O_{z} interlayer dielectric (ILD) located below the conductive line 1003 with the two or more vias 1005 of the BEOL interconnect structure 1001, 7001, 8001. In still further options, the low-k MnₓSi_{y}O_{z} dielectric can be a low-k MnₓSi_{y}O_{z} interlayer dielectric (ILD) that both surrounds the conductive line 1003 and is located below the conductive line 1003 with the two or more vias 1005 of the BEOL interconnect structure 1001, 7001, 8001.

Continuing with options, an area between the two or more vias 1005 can exclude an air gap 4013 and can include the low-k MnₓSi_{y}O_{z} dielectric.

Still further, optionally, the BEOL interconnect structure 1001, 7001, 8001 can further include a metal liner 1009 located between the low-k MnₓSi_{y}O_{z} dielectric and the conductive line 1003 and between the low-k MnₓSi_{y}O_{z} dielectric and the two or more vias 1005, in which a thickness of the metal liner 1009 is equal to or less than 1 nm.

In accordance with further aspects of the invention, an exemplary semiconductor structure 1000 includes an air gap 4013 back-end-of-line (BEOL) interconnect structure 1001, 4001, 5001, 6001 having a plurality of wiring levels M0-M15, in which a wiring level of the plurality of wiring levels M0-M15 includes a conductive line 1003, two or more vias 1005 electrically connecting two or more levels of the plurality of wiring levels M0-M15, and an air gap 4013 located between the two or more vias 1005, and a low-k MₓSi_{y}O_{z} dielectric associated with the conductive line 1003 and the two or more vias 1005, where M is a metal.

The M in the low-k MₓSi_{y}O_{z} dielectric can, in some instances, be Mn and the low-k MₓSi_{y}O_{z} dielectric accordingly can be low-k Manganese-Silicate (MnₓSi_{y}O_{z}) dielectric. M can be other materials in other cases as noted herein (e.g., Magnesium (Mg); Aluminum (Al); Cobalt (Co); Tungsten (W); and Molybdenum (Mo)).

Optionally, the low-k MₓSi_{y}O_{z} dielectric can include 1-10% Manganese (Mn), less than 33% Silicon (Si), and less than 60% Oxygen (O). Further, optionally, the low-k MₓSi_{y}O_{z} dielectric can have a modulus equal to or greater than 75 GPa, a low-k value range of 3.7-4.2, a porosity of 0-25%, or any combination thereof.

In still further options, a pitch between the two or more vias 1005 can be equal to or less than 18 nm.

Optionally, the low-k MₓSi_{y}O_{z} dielectric can be a low-k MnₓSi_{y}O_{z} dielectric liner 5017 located on the sidewalls of the two or more vias 1005.

Continuing with options, the low-k MₓSi_{y}O_{z} dielectric can be a low-k MnₓSi_{y}O_{z} dielectric cap 5015.

In still further options, the low-k MₓSi_{y}O_{z} dielectric is a low-k MnₓSi_{y}O_{z} interlayer dielectric (ILD) that surrounds the conductive line 1003 of the BEOL interconnect structure 1001, 4001, 5001, 6001 or is located below the conductive line 1003 with the two or more vias 1005 of the BEOL interconnect structure 1001, 4001, 5001, 6001. Further, optionally, the low-k MₓSi_{y}O_{z} dielectric can be a low-k MnₓSi_{y}O_{z} interlayer dielectric (ILD) that both surrounds the conductive line 1003 and is located below the conductive line 1003 with the two or more vias 1005 of the BEOL interconnect structure 1001, 4001, 5001, 6001. In further options, the low-k MₓSi_{y}O_{z} can be a low-k MₓSi_{y}O_{z} interlayer dielectric (ILD) that both surrounds the conductive line 1003 and is located below the conductive line 1003 with the two or more vias 1005 of the BEOL interconnect structure 1001, 4001, 5001, 6001, in which the Mₓ includes a 0.5-10 atomic percent and can be selected from the group 1011 including Manganese (Mn), Magnesium (Mg), Aluminum (Al), Cobalt (Co), Tungsten (W), and Molybdenum (Mo).

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of an exemplary backside power delivery network with pillar embedded in cooling channel as disclosed herein.

An integrated circuit in accordance with aspects of the present inventions can be employed in essentially any application and/or electronic system where one or more aspects of the exemplary backside power delivery network (BSPDN) with pillar embedded in cooling channel as disclosed herein would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods can occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose may be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom,” “top,” “above,” “over,” “under,” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a back-end-of-line (BEOL) interconnect structure comprising:
a plurality of wiring levels, wherein a wiring level of the plurality of wiring levels comprises:
a conductive line; and
two or more vias electrically connecting two or more levels of the plurality of wiring levels; and
a low-k MₓSi_{y}O_{z} dielectric associated with the conductive line and the two or more vias, where M is a metal.

2. The semiconductor structure of claim 1, wherein the M in the low-k MₓSi_{y}O_{z} dielectric comprises Mn and the low-k MₓSi_{y}O_{z} dielectric accordingly comprises low-k Manganese-Silicate (MnₓSi_{y}O_{z}) dielectric.

3. The semiconductor structure of claim 2, wherein the conductive line and two or more vias are selected from the group consisting of:
Copper (Cu);
Ruthenium (Ru);
Rhodium (Rh);
Cobalt (Co);
Tungsten (W);
Copper-Aluminum (CuAl);
Iridium (Ir); and
Molybdenum (Mo).

4. The semiconductor structure of claim 2, wherein the low-k MnₓSi_{y}O_{z} dielectric comprises 1-10% Manganese (Mn), less than 33% Silicon (Si), and less than 60% Oxygen (O).

5. The semiconductor structure of claim 2, wherein the low-k MnₓSi_{y}O_{z} dielectric has a modulus equal to or greater than 75 GPa, a low-k value range of 3.7-4.2, a porosity of 0-25%, or any combination thereof.

6. The semiconductor structure of claim 2, wherein the low-k MnₓSi_{y}O_{z} dielectric has a thickness equal to or less than 20 nm.

7. The semiconductor structure of claim 2, wherein a pitch between the two or more vias is equal to or less than 18 nm.

8. The semiconductor structure of claim 2, wherein the low-k MnₓSi_{y}O_{z} dielectric further comprises Nitrogen (MnₓSi_{y}O_{z}Nᵥ) or Nitrogen and Carbon (MnₓSi_{y}O_{z}NᵥC_{w}).

9. The semiconductor structure of claim 2, wherein the low-k MnₓSi_{y}O_{z} dielectric is a low-k MnₓSi_{y}O_{z} dielectric cap.

10. The semiconductor structure of claim 2, wherein the low-k MnₓSi_{y}O_{z} dielectric surrounds the conductive line of the BEOL interconnect structure.

11. The semiconductor structure of claim 2, wherein the low-k MnₓSi_{y}O_{z} dielectric is located below the conductive line with the two or more vias of the BEOL interconnect structure.

12. The semiconductor structure of claim 2, wherein the low-k MnₓSi_{y}O_{z} both surrounds the conductive line and is located below the conductive line with the two or more vias of the BEOL interconnect structure.

13. The semiconductor structure of claim 2, wherein an area between the two or more vias excludes an air gap and includes the low-k MnₓSi_{y}O_{z} dielectric.

14. The semiconductor structure of claim 2, wherein the BEOL interconnect structure further comprises a metal liner located between the low-k MnₓSi_{y}O_{z} dielectric and the conductive line and between the low-k MnₓSi_{y}O_{z} dielectric and the two or more vias, wherein a thickness of the metal liner is equal to or less than 1 nm.

15. The semiconductor structure of claim 1, wherein, in the low-k MₓSi_{y}O_{z} dielectric, the M comprises a 0.5-10 atomic percent and is selected from the group consisting of:
Manganese (Mn);
Magnesium (Mg);
Aluminum (Al);
Cobalt (Co);
Tungsten (W); and
Molybdenum (Mo).

16. A semiconductor structure comprising:
an air gap back-end-of-line (BEOL) interconnect structure comprising:
a plurality of wiring levels, wherein a wiring level of the plurality of wiring levels comprises:
a conductive line;
two or more vias electrically connecting two or more levels of the plurality of wiring levels; and
an air gap located between the two or more vias; and
a low-k MₓSi_{y}O_{z} dielectric associated with the conductive line and the two or more vias, where M is a metal.

17. The semiconductor structure of claim 16, wherein the M in the low-k MₓSi_{y}O_{z} dielectric comprises Mn and the low-k MₓSi_{y}O_{z} dielectric accordingly comprises low-k Manganese-Silicate (MnₓSi_{y}O_{z}) dielectric.

18. The semiconductor structure of claim 17, wherein the low-k MₓSi_{y}O_{z} dielectric comprises 1-10% Manganese (Mn), less than 33% Silicon (Si), and less than 60% Oxygen (O).

19. The semiconductor structure of claim 17, wherein the low-k MₓSi_{y}O_{z} dielectric has a modulus equal to or greater than 75 GPa, a low-k value range of 3.7-4.2, a porosity of 0-25%, or any combination thereof.

20. The semiconductor structure of claim 17, wherein a pitch between the two or more vias is equal to or less than 18 nm.
